(19) United States
(12) Patent Application Publication
(10) Pub. No.: US 2009/0015141 A1
(43) Pub. Date: Jan. 15, 2009

(54) Electronic Device Having An Optical Resonator

(75) Inventors: Jian Wang, Goleta, CA (US); Gang Yu, Santa Barbara, CA (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. du Pont de Nemours and Company, Wilmington, DE (US)

(21) Appl. No.: 11/721,585

(22) PCT Filed: Dec. 21, 2005
(86) PCT No.: PCT/US2005/046101

§ 371 Date: Oct. 7, 2008

Related U.S. Application Data
(60) Provisional application No. 60/640,783, filed on Dec. 30, 2004.
(60) Provisional application No. 60/694,874, filed on Jun. 28, 2005.

(51) Int. Cl. H01J 1/62; H01J 9/00

(52) U.S. Cl. 313/504; 313/323; 445/1

(57) ABSTRACT

An optical resonator is provided, and methods for making the same, as well as devices and sub-assemblies including the same. For example, such an electronic device (FIG. 4) may include a first electronic component (172) designed to be photoactive to radiation having a first wavelength and a second electronic component (174) designed to be photoactive to radiation having a second wavelength. The device may also include a cavity that defines an optical resonator having a cavity length such that the optical resonator resonates in successive resonant modes that locate at the first and second wavelengths.

### CROSS REFERENCE

This application claims benefit to U.S. Provisional Application Ser. Nos. 60/640,783, filed Dec. 30, 2004, and 60/694,874, filed Jun. 28, 2005. Furthermore, this application is related to U.S. patent application having Attorney Docket No. DPUC-0183/UC0508 PCT NA, which was filed Dec. 21, 2005. The disclosures of all of the above applications are incorporated by reference herein in their entireties.

### FIELD

This disclosure relates generally to electronic devices and processes, and more specifically to electronic devices having an optical resonator, and materials and methods for fabrication of the same.

### BACKGROUND

Organic electronic devices convert electrical energy into radiation, detect signals through electronic processes, convert radiation into electrical energy, or include one or more organic semiconductor layers. Organic electronic devices can used in displays, sensor arrays, photovoltaic cells, etc. Small molecule organic light-emitting diodes (“SMOLEDs”) and polymer light-emitting diodes (“PLEDs”), both of which are organic light-emitting diodes (“OLEDs”), are types of organic electronic displays. Realizing full colors in such displays, however, has been problematic. For example, it is difficult to fabricate organic materials having color purity that meets CIE standards, because most organic materials have broad emissive or transmissive spectra. Conventional attempts to overcome this shortcoming tend to involve complicated fabrication processes, or produce a device having poor readability or low contrast.

Thus, what is needed are organic electronic devices that address the above shortcomings and drawbacks.

### SUMMARY

In one embodiment, an electronic device is provided, and methods for making the same, as well as devices and sub-assemblies including the same. For example, such an electronic device may include a first electronic component designed to be photoactive to radiation having a first wavelength and a second electronic component designed to be photoactive to radiation having a second wavelength. The device may also include a cavity that defines an optical resonator having a cavity length such that the optical resonator resonates in successive resonant modes that locate at the first and second wavelengths.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes an illustration of a Fabry-Perot etalon;

FIG. 2 includes an illustration of a non-symmetric optical resonator;

FIG. 3 includes a plot of wavelength versus normalized spectra for three resonant modes in an optical resonator;

FIG. 4 includes an illustration of a cross-sectional view of a portion of a substrate after forming electronic components;

FIG. 5 includes an illustration of a cross-sectional view of the substrate of FIG. 1 after forming a planarized insulating layer between the electronic components;

FIG. 6 includes an illustration of a cross-sectional view of an OLED device having an optical resonator fabricated on the cathode side of the device;

FIG. 7 includes a plot of wavelength versus normalized spectra for emitters having different wavelengths in accordance with an embodiment;

FIG. 8 includes an illustration of a cross-sectional view of a top emission OLED device inside an optical resonator in accordance with an embodiment;

FIG. 9 includes a plot of wavelength versus normalized spectra for emitters having different wavelengths in accordance with an embodiment;

FIG. 10 includes an illustration of a stacked emitter OLED device inside an optical resonator having a Bragg reflector in accordance with an embodiment; and

FIG. 11 includes an illustration of a stacked emitter OLED device inside an optical resonator having a mirror in accordance with an embodiment.

The figures are provided by way of example and are not intended to limit the invention. Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

In one embodiment, an electronic device is provided. The electronic device includes a first electronic component designed to be photoactive to a first radiation having a first wavelength, a second electronic component designed to be photoactive to a second radiation having a second wavelength and a cavity that defines an optical resonator, where the cavity has a length such that the optical resonator resonates in successive resonant modes that locate at the first and second wavelengths.

In one embodiment, the cavity is formed from a first and a second layer of the electronic device.

In one embodiment, the optical resonator further comprises at least one resonating layer through which the first and second radiation resonates.

In one embodiment, the resonating layer is bordered on one side by a first reflective layer and on a second side by a second reflective layer, wherein the first reflective layer reflects into the resonating layer at least a portion of the first and second radiation.

In one embodiment, the second reflective layer at least partially permits the first and second radiation to pass through the second reflective layer is provided.

In one embodiment, the electrical device further comprises a plurality of layers, and wherein the resonating layer is bordered on one side by an interface formed by at least two of the plurality of layers.

In one embodiment, a third electronic component is designed to be photoactive to a third radiation having a third wavelength, and the cavity length of the optical resonator is such that the optical resonator further resonates in a resonant mode that locates at the third wavelength.

In one embodiment, the first and second electronic components are arranged in a stacked or lateral configuration.

In one embodiment, an organic light emitting device is provided. The electronic device includes a substrate, a cathode layer, an anode layer and a light-emitting layer that emits light in each of red, green, and blue visible regions through the substrate in response to a current applied between the cathode layer and the anode layer. The electronic device further includes an optical resonator, the optical resonator comprising at least one resonating layer through which the light resonates, where the light resonates in at least three successive resonant modes, and further where the three successive resonant modes correspond to red, green, and blue visible regions.

In one embodiment, the resonating layer is bordered on one side by a first reflective layer and on a second side by a second reflective layer, where each of the first and the second reflective layers reflects back into the resonating layer at least some portion of the light resonating through the resonating layer onto the reflective layer.

In one embodiment, a process for forming an electronic device is provided. The process includes forming a first electronic component designed to be photoactive to a first radiation having a first wavelength, forming a second electronic component designed to be photoactive to a second radiation having a second wavelength and forming a cavity that defines an optical resonator having a cavity length such that the optical resonator resonates in successive resonant modes that locate at the first and second wavelengths.

In one embodiment, the process further includes forming a substrate forming an anode layer and forming a cathode layer; wherein the optical resonator is formed on a side of the electronic device corresponding to the cathode layer.

In one embodiment, the optical resonator further comprises at least one resonating layer through which the first and second radiation resonates.

In one embodiment, the resonating layer is bordered on one side by a first reflective layer and on a second side by a second reflective layer, wherein the first reflective layer reflects into the resonating layer at least a portion of the first and second radiation.

In one embodiment, the second reflective layer at least partially permits the first and second radiation to pass through the second reflective layer.

In one embodiment, where the process further includes forming a third electronic component designed to be photoactive to a third radiation having a third wavelength; and wherein the cavity length of the optical resonator is such that the optical resonator further resonates in a resonant mode that locates at the third wavelength.

In one embodiment, a composition including the electronic device discussed above is provided.

In one embodiment, an organic electronic device having an active layer including the electronic device discussed above is provided.

In one embodiment, an article useful in the manufacture of an organic electronic device, comprising the electronic device discussed above is provided.

In one embodiment, compositions are provided comprising the above-described compounds and at least one solvent, processing aid, charge transporting material, or charge blocking material. These compositions can be in any form, including, but not limited to solvents, emulsions, and colloidal dispersions.

### DEFINITIONS

The use of “a” or “an” are employed to describe elements and components of the invention. This is done merely for convenience and to give a general sense of the invention. This description should be read to include one or at least one and the singular also includes the plural unless it is obvious that it is meant otherwise.

The term “active” when referring to a layer or material is intended to mean a layer or material that exhibits electronic or electro-radiative properties. An active layer material may emit radiation or exhibit a change in concentration of electron-hole pairs when receiving radiation. Thus, the term “active material” refers to a material which electronically facilitates the operation of the device. Examples of active materials include, but are not limited to, materials which conduct, inject, transport, or block a charge, where the charge can be either an electron or a hole. Examples of inactive materials include, but are not limited to, planarization materials, insulating materials, and environmental barrier materials.

The term “actual thickness” is intended to mean a thickness of one or more layers within an electronic device or other physical object.

The term “adjacent,” does not necessarily mean that a layer, member or structure is immediately next to another layer, member or structure. A combination of layer(s), member(s) or structure(s) that directly contact each other are still adjacent to each other.

The term “adjacent to,” when used to refer to any combination of one or more layers, one or more members, or one or more structures in a device, does not necessarily mean that one layer, member, or structure is immediately next to another layer, member or structure. Layer(s), member(s) or structure(s) that directly contact each other are still adjacent to each other.

The terms “array,” “peripheral circuitry,” and “remote circuitry” are intended to mean different areas or components of an electronic device. For example, an array may include pixels, cells, or other structures within an orderly arrangement (usually designated by columns and rows). The pixels, cells, or other structures within the array may be controlled by peripheral circuitry, which may lie on the same substrate as the array but outside the array itself. Remote circuitry typically lies away from the peripheral circuitry and can send signals to or receive signals from the array (typically via the peripheral circuitry). The remote circuitry may also perform functions unrelated to the array. The remote circuitry may or may not reside on the substrate having the array.

The term “blue light-emitting organic layer” is intended to mean an organic layer capable of emitting radiation that has an emission maximum at a wavelength in a range of approximately 400 to 500 nm.

The term “calculated thickness” is intended to mean a thickness of one or more layers that is determined by an equation. An actual thickness and a calculated thickness may be the same or different from each other.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The term “electronic component” is intended to mean a lowest level unit of a circuit that performs an electrical or electro-radiative (e.g., electro-optic) function. An electronic component may include a transistor, a diode, a resistor, a capacitor, an inductor, a semiconductor laser, an optical switch, or the like. An electronic component does not include parasitic resistance (e.g., resistance of a wire) or parasitic capacitance (e.g., capacitive coupling between two conductors electrically connected to different electronic components where a capacitor between the conductors is unintended or incidental).

The term “electronic device” is intended to mean a collection of circuits, electronic components, or combinations thereof that collectively, when properly electrically connected and supplied with the appropriate potential(s), performs a function. An electronic device may include or be part of a system. An example of an electronic device includes a display, a sensor array, a computer system, an avionics system, an automobile, a cellular phone, other consumer or industrial electronic product, or any combination thereof.

The term “green light-emitting organic layer” is intended to mean an organic layer capable of emitting radiation that has an emission maximum at a wavelength in a range of approximately 500 to 600 nm.

The term “immediately adjacent” is intended to mean that two or more objects are near each other and that no other significant object lies between such two or more objects. In one embodiment, the two or more objects touch each other. In another embodiment, two or more objects may be separated by an insignificant gap (e.g., a contiguous arrangement). Any of the objects can include a layer, member, structure, or any combination thereof.

The term “layer” is used interchangeably with the term “film” and refers to a coating covering a desired area. The area can be as large as an entire device or a specific functional area such as the actual visual display, or as small as a single sub-pixel. Films can be formed by any conventional deposition technique, including vapor deposition and liquid deposition. Liquid deposition techniques include, but are not limited to, continuous deposition techniques such as spin coating, gravure coating, curtain coating, dip coating, slot-die coating, spray-coating, and continuous nozzle coating; and discontinuous deposition techniques such as ink jet printing, gravure printing, and screen printing.

The term “mirror stack” is intended to mean a plurality of layers, wherein the plurality of layers acts a mirror. In one embodiment, a mirror stack can include one or more Bragg reflectors.

The term “organic active layer” is intended to mean one or more organic layers, wherein at least one of the organic layers, by itself, or when in contact with a dissimilar material is capable of forming a rectifying junction.

The term “organic electronic device” is intended to mean a device including one or more semiconductor layers or materials. Organic electronic devices include, but are not limited to: (1) devices that convert electrical energy into radiation (e.g., a light-emitting diode, light emitting diode display, diode laser, or lighting panel), (2) devices that detect signals through electronic processes (e.g., photodetectors photoconductive cells, photoresistors, photoswitches, phototransistors, phototubes, infrared (“IR”) detectors, or biosensors), (3) devices that convert radiation into electrical energy (e.g., a photovoltaic device or solar cell), and (4) devices that include one or more electronic components that include one or more organic semiconductor layers (e.g., a transistor or diode). The term device also includes coating materials for memory storage devices, antistatic films, biosensors, electrochromic devices, solid electrolyte capacitors, energy storage devices such as a rechargeable battery, and electromagnetic shielding applications.

The term “organic layer” is intended to mean one or more layers, wherein at least one of the layers comprises a material including carbon and at least one other element, such as hydrogen, oxygen, nitrogen, fluorine, etc.

The term “pair of layers” is intended to mean an even number of layers and can include 2, 4, 6, 8, or more layers.

“Photoactive” refers to a material that emits light when activated by an applied voltage (such as in a light emitting diode or chemical cell) or responds to radiant energy and generates a signal with or without an applied bias voltage (such as in a photodetector).

The term “radiation-emitting component” is intended to mean an electronic component, which when properly biased, emits radiation at a targeted wavelength or spectrum of wavelengths. The radiation may be within the visible-light spectrum or outside the visible-light spectrum (UV or IR). A light-emitting diode is an example of a radiation-emitting component.

The term “radiation-responsive component” is intended to mean an electronic component, which when properly biased, can respond to radiation at a targeted wavelength or spectrum of wavelengths. The radiation may be within the visible-light spectrum or outside the visible-light spectrum (UV or IR). An IR sensor and a photovoltaic cell are examples of radiation-sensing components.

The term “rectifying junction” is intended to mean a junction within a semiconductor layer or a junction formed by an interface between a semiconductor layer and a dissimilar material, in which charge carriers of one type flow easier in one direction through the junction compared to the opposite direction. A pn junction is an example of a rectifying junction that can be used as a diode.

The term “red light-emitting organic layer” is intended to mean an organic layer capable of emitting radiation that has an emission maximum at a wavelength in a range of approximately 600 to 700 nm.

The term “substrate” is intended to mean a workpiece that can be either rigid or flexible and may include one or more layers of one or more materials, which can include, but are not limited to, glass, polymer, metal, or ceramic materials, or combinations thereof.

The term “user surface” is intended to mean a surface of the electronic device principally used during normal operation of the electronic device. In the case of a display, the surface of the electronic device seen by a user would be a user surface. In the case of a sensor or photovoltaic cell, the user surface would be the surface that principally transmits radiation that is to be sensed or converted to electrical energy. Note that an electronic device may have more than one user surface.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### EXAMPLES

The concepts described herein will be further described in the following examples, which do not limit the scope of the invention described in the claims.

The use of an optical resonator in connection with an electronic device having one or more Bragg reflectors is discussed in commonly-assigned U.S. patent application having Attorney Docket No. DPUC-0183/UC0508 PCT NA, which was filed Dec. 21, 2005, and which is incorporated by reference herein in its entirety.

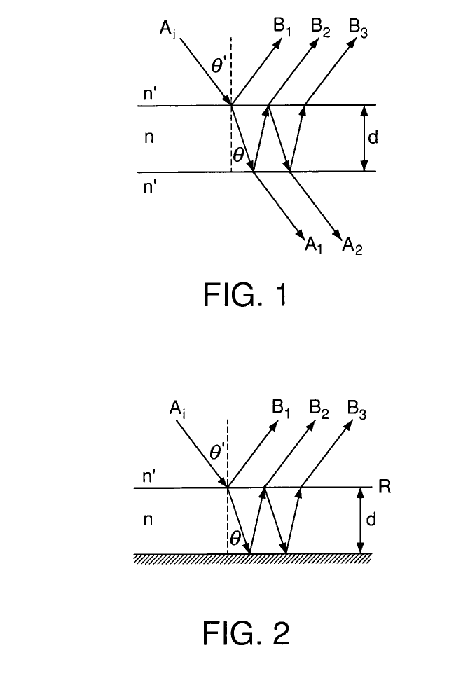

An optical resonator provides a location in which light can resonate. Typically, light resonates between two reflective layers that border the cavity. The cavity can be hollow or comprised of any material through which light can pass. The reflective layers may be wholly or partially reflective, and may also serve other purposes such as, for example, an anode, cathode or substrate. Typical optical resonators include two or more mirrors that, by repeated reflections, resonate an optical beam at a selected wavelength determined by the cavity length of the resonator. The Fabry-Perot etalon is considered to be the archetype of the optical resonator. Its structure and an example optical beam propagation are illustrated in FIG. 1. Other example configurations for an optical resonator are described below. Embodiments of the present invention contemplate any configuration for an optical resonator.

The Fabry-Perot etalon shown in FIG. 1 consists of a plane-parallel plate of thickness d and index of refraction n that is immersed in a medium of index of refraction n′. A plane wave with complex amplitude of Aᵢ is incident on the etalon at an angle θ′ to the normal. The refracted light enters the etalon at an angle θ to the normal. A₁, A₂, and so forth, are the complex amplitudes of partial transmitted lights, while B₁, B₂, B₃, and so forth, are the complex amplitudes of partial reflected lights.

Referring now to FIG. 1, whenever the path difference between two successive transmissions (e.g., A₁ and A₂) is equal to the integral multiple of the wavelength, the transmission light intensity reaches a maximum.

2nd cos θ=kλ (1)

wherein:
n is the index of refraction of the etalon;
d is the etalon thickness;
λ is the vacuum wavelength of the incident wave;
θ is the refraction angle within the etalon;
and
k is the order number.

The full width at half maximum value of the transmission peak depends on the reflections coefficient of the etalon surface. The finesse (F) of the etalon is defined as:

$$F ≡ \frac{π \sqrt{R}}{1 - R} = \frac{1}{k} \frac{λ}{Δλ} \qquad ( 2 )$$

wherein:
R is the reflectance of the etalon surface;
λ is the vacuum wavelength of the incident wave;
Δλ is the full-width at half-maximum (“FWHM”) value of the transmission peak; and
k is the order number.

From Eqs. (1) and (2), it may be seen that a resonate wavelength may be selected by adjusting the cavity length. The FWHM of the transmission peak may be changed by changing the reflectance of the etalon surface. It will be appreciated that the above example pertains to a symmetric optical resonator. An embodiment of the invention may also be based on, for example, a non-symmetric optical resonator as depicted in FIG. 2.

In a non-symmetric optical resonator, the bottom surface may have provide substantially complete reflectance, which means that there may be no transmission light. The resonance condition for a normal incident beam is:

2nd=kλ (3)

wherein:
n is the index of refraction of the optical resonator;
d is the resonator's thickness;
λ is the vacuum wavelength of the incident wave transmission peak wavelength; and
k is the order number.

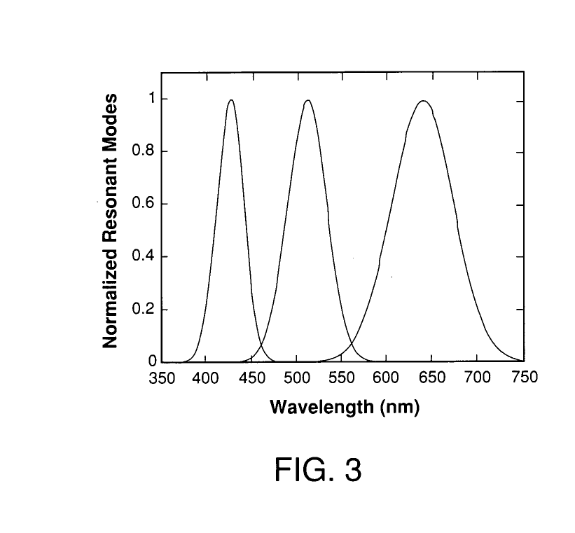

The cavity length may be adjusted to make the resonator have three successive resonant modes that locate at the red, green and blue visible regions. The order numbers for red, green and blue may be 4, 5 and 6, respectively. The light path length may be 2560 nm, for example, which may result in three resonant modes at 640 nm, 512 nm and 427 nm. If the light path length is too short, the optical resonator may not be able to sustain three resonant modes in the visible region. If it is too long, the optical resonator may have many resonant modes, which may lead to a mixture of unnecessary colors with the primary colors. Thus, the light path length may be in the range of about 2400 nm to about 2800 nm. The exact value may depend on the actual application and the required colors, among other possible factors. By changing the reflectance of the optical resonator's top surface, the finesse may be adjusted. For example, a finesse value of two may result in a FWHM of 80 nm, 51 nm and 35 nm, for red (640 nm), green (512 nm) and blue (427 nm), respectively. The plot depicted in FIG. 3 shows an example dependence of reflected light intensity on wavelength, where lines 301, 303 and 305 represent a wavelength associated with blue, green and red, respectively.

In an embodiment, the resonant modes may have CIE color coordinates of (0.649, 0.350), (0.120, 0.602) and (0.165, 0.010), for red, green and blue, respectively. When a white light with a constant power distribution spectrum over the entire visible region is incident on the optical resonator, only the resonant modes may be reflected. As a result, the reflected light intensity may be approximately 44% of the incident intensity (the ratio of the total area between the resonant curves and x-axis to the total area between y=1 and x-axis over the visible region from 380 nm to 780 nm). In a full color OLED device, for example, the primary color emitter's emission may be modified by the optical resonator, which may cause the color coordinates to be improved. In addition, the reflected ambient light intensity may be reduced by the optical resonator, which may lead to a better contrast ratio.

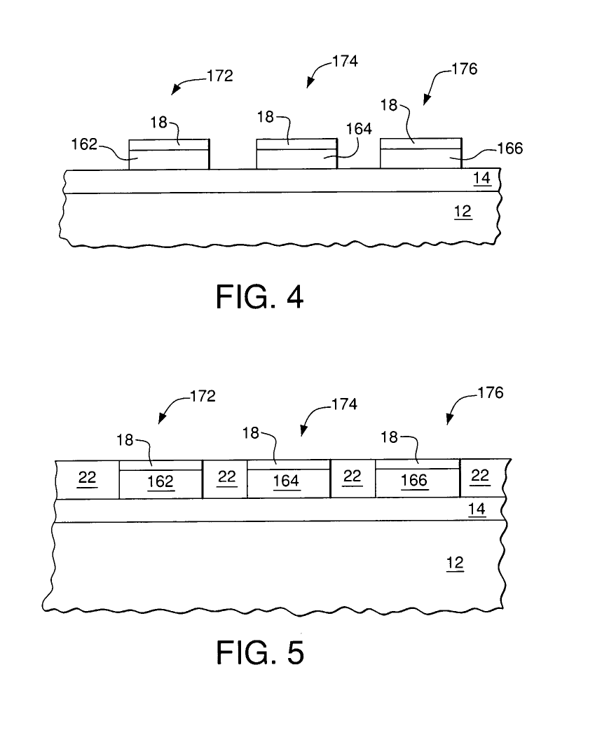

FIG. 4 includes an illustration of a cross-sectional view of a portion of substrate 12 over which electronic components 172, 174 and 176 have been fabricated during the formation of an electronic device. Substrate 12 can include one or more layers that can include an insulating material, such as glass or other ceramic material, plastic, or any combination thereof. Substrate 12 may be rigid or flexible, and may or may not allow radiation to be transmitted. In one embodiment, the user side of the electronic device is opposite substrate 12. In this embodiment, the transmission of radiation through-substrate 12 is not important. In another embodiment, the user side of the electronic device lies on the side of substrate 12 opposite the side of electronic components 172, 174 and 176. In this embodiment, at least 70% of the radiation to be emitted or responded to by electronic components 172, 174 and 176 may be transmitted through substrate 12. In the embodiment illustrated in FIGS. 4-6 and 8, a top-emission electronic device (i.e., where emission occurs away from substrate 12) is being formed, and thus, the transmission of radiation through substrate 12 is not important.

First electrode 14 may be formed over substrate 12. In one embodiment, first electrode 14 can act as a common anode for the display. In another embodiment, first electrode 14 could be replaced by a plurality of first electrodes that may be coupled to control circuits (not illustrated) within substrate 12. First electrode 14 can include one or more layers of one or more materials that are conventionally used for anodes within OLEDs. First electrode 14 can reflect part or substantially all radiation incident on first electrode 14. In one particular embodiment, first electrode 14 can include a first layer and a second layer (not shown), wherein the first layer lies closer to substrate 12 as compared to the second layer. The first layer may reflect part or substantially all of the radiation reaching the first layer and can include silver, aluminum, other partially or highly reflective, conductive material, or any combination thereof. The second layer can include a relatively more transparent layer as compared to the first layer and may include indium tin oxide (“ITO”), indium zinc oxide (“IZO”), aluminum zinc oxide (“AZO”) or the like. First electrode 14 can include a conductive organic polymer in another embodiment, and may be formed using a conventional deposition technique, for example.

Organic layers 162, 164 and 166 can be formed over first electrode 14. Organic layers 162, 164 and 166 can have substantially the same or different compositions and have one or more layers. For example, organic layers 162, 164 and 166 may have the same or different organic active layers. In one embodiment, organic layer 162 may include a blue light-emitting organic layer, organic layer 164 may include a green light-emitting organic layer and organic layer 166 may include a red light-emitting organic layer. In another embodiment, each of organic layers 162, 164 and 166 may include a white light-emitting organic layer. In still another embodiment, one or more other organic layers may be used in conjunction with the organic active layer(s). Such other layer(s) can include a buffer layer, a charge-blocking layer, a charge-injection layer, a charge-transport layer or any combination thereof. In still another embodiment, any of organic layers 162, 164 and 166 may include a single layer, wherein different portions of the single layer serves different purposes (e.g., one portion acts as a hole-transport layer and another portion acts as an electroluminescent layer). In still a further embodiment, any one or more of organic layers 162, 164 and 166 may be designed to respond to radiation such as, for example, a sensor or photovoltaic cell. The composition and thickness of organic layers 162, 164 and 166 may be conventional, for example.

The composition and thickness of organic layers 162, 164 and 166 can be conventional. In one embodiment, each layer within each of organic layers 162, 164 and 166 can include a small molecule or polymer (which may or may not include a copolymer) material. A conventional deposition can be used to form any one or more of organic layers 162, 164 and 166. The deposition can include a chemical vapor deposition, physical vapor deposition (e.g., evaporation, sputtering or the like), casting, spin coating, ink-jet printing, continuous printing, etc. Each of organic layers 162, 164 and 168 may be patterned as deposited or may be deposited and subsequently patterned. In an alternative embodiment, one or more substrate structures (not illustrated) may be formed over substrate 12 before forming organic layers 162, 164 and 166. An example of a substrate structure can include a well structure, a cathode separator or the like.

Second electrodes 18 may be formed over organic layers 162, 164 and 166. Second electrodes 18 can act as cathodes for electronic components 172, 174 and 176. In one embodiment, second electrodes 18 may include a first layer and a second layer, wherein the first layer lies closer to organic layers 162, 164 and 166 as compared to the second layer. The first layer can include a material that has a relatively low work function, for example. An example of such a material may include, for example, a Group 1 metal (e.g., Li, Cs, or the like), a Group 2 (alkaline earth) metal (e.g., Mg, Ca, or the like), an alkali metal compounds (e.g., Li₂O, LiBO₂, or the like), a rare earth metal including a lanthanide or an actinide, an alloy of any such metals, or any combination thereof. The first layer can also include alkali fluorides or alkaline earth fluorides, such as, for example, LiF, CsF, MgF₂, CaF₂, or the like. A conductive polymer with a low work function may also be used.

The second layer may include a material that helps to protect the first layer during processing of the electronic device. The second layer can be more stable in air as compared to the first layer. The second layer can include, for example, ITO, IZO, AZO, Ag, Al or any combination thereof. Second electrodes 18 may be transparent or partially transparent to radiation that is emitted from organic layers 162, 164 and 166 or radiation to which organic layers 162, 164 and 166 are designed to respond. In one particular embodiment, the second layer partially reflects radiation.

Second electrodes 18 can be patterned as deposited or can be deposited and subsequently patterned using one or more conventional techniques. Although not illustrated, in finished electronic device, second electrodes 18 may be coupled to control circuits. Alternatively, if separate first electrodes would be used, a common second electrode may also be used. In an embodiment, second electrode 18 has a thickness of up to 1 micron.

Optional planarization layer 22 may be formed between electronic components 172, 174 and 176, as illustrated in FIG. 5. Planarization layer 22 can help reduce topology changes for subsequently-formed layers such as, for example, mirror stacks. Planarization layer 22 may include one or more layers of an organic or inorganic electrically insulating material. Planarization layer 22 may be patterned as deposited or deposited and subsequently patterned. The elevations of the top surfaces of planarization layer 22 can be approximately the same as the top surfaces of second electrodes 18. In another embodiment, the elevations may be significantly different.

In still another embodiment, a substrate structure (not illustrated) may be present between electronic components 172, 174 and 176. In an embodiment, planarization layer 22 may be formed within openings of the substrate structure such that the top surfaces of the substrate structure and planarization layer 22 are at approximately the same elevation. In another embodiment, the tops surfaces may be significantly different. In yet another embodiment, planarization layer 22, substrate structure, or both are not used.

Other circuitry not illustrated in FIGS. 4 and 5 may be formed using any number of the previously described or additional layers. Although not shown, additional insulating layer(s) and interconnect level(s) may be formed to allow for circuitry in peripheral areas (not shown) that may lie outside the array. Such circuitry may include row or column decoders, strobes (e.g., row array strobe, column array strobe or the like), sense amplifiers, etc. For example, a lid with an optional desiccant (not illustrated) can be attached to substrate 12 at locations (not illustrated) outside the array to form an electronic device that is substantially completed. In one embodiment, radiation is transmitted through the lid. If radiation within the visible light spectrum is emitted from or to be received by the electronic device, at least 70% of the radiation incident on the lid is to be transmitted through the lid. In one embodiment, the lid may include glass. If radiation does not need to be emitted or received by electronic components 172, 174 and 176 via the lid, the lid may or may not be capable of transmitting the radiation. In such an embodiment, the lid may include any one or more of a wide variety of materials, including glass, metal or the like. One or more materials used for the lid and the attaching process may be conventional.

If a desiccant is used, the location of the desiccant can depend on whether the desiccant can allow sufficient radiation that is to be emitted from or received by the electronic device. If radiation within the visible light spectrum is emitted from or to be received by the electronic device, at least 70% of the radiation incident on the desiccant may be transmitted through the desiccant. If the desiccant does not allow sufficient radiation to be transmitted, it may lie at one or more locations where it would not substantially interfere with the transmission of radiation. Such locations can include outside the array, or from a top view of the electronic device, at locations between electronic components 172, 174 and 176. If radiation does not need to be emitted or received by electronic components 172, 174 and 176 via the desiccant, the desiccant can be located at nearly any position along the lid.

In an embodiment, the electronic device may include an active matrix or passive matrix display. Other electronic components (not illustrated) can be formed within or over substrate 12 or within or over another substrate, wherein such other electronic components may provide or control signals provided to the electronic components, including electronic components 172, 174 and 176, within an array. Such other electronic components and their fabrication, attachment to substrate 12, or both should be known to one of skill in the art.

In an embodiment, an optical resonator may be formed using any of the aforementioned layers, or an interface between any of the layers, to serve as a reflective surface of one side of the optical resonator. For example, an interface between second electrode 18, planarization layer 22 or the like, and an additional layer (not shown) may form one side of an optical resonator, and first electrode 14 or the like may form the other side of the resonator. The thickness, composition or the like of any of such layers may be adjusted to obtain a resonator with the appropriate characteristics (i.e., cavity length, finesse, etc.). One side of the resonator may be substantially completely reflective while another side may be partially reflective. It will be appreciated that the partially reflective surface is a surface through which light is emitted from the device. Examples 1-4, below, illustrate various example configurations of an electronic device having an optical resonator according to an embodiment.

The electronic device may include radiation-responsive components in addition to or in place of radiation-emitting components. In one embodiment, the radiation-responsive components can be radiation sensors within a sensor array. The radiation sensors may be designed to respond to radiation at a particular wavelength or spectrum of wavelengths. In one embodiment, an array may include radiation-emitting components and sensors. In still another embodiment, the radiation-responsive components are photovoltaic cells or other electronic components capable of converting radiation to energy.

During operation of a display, appropriate potentials are placed on first electrode 14 and any one or more of second electrodes 18 to cause radiation to be emitted from one or more of organic layers 162, 164 or 166. More specifically, when light is to be emitted, a potential difference between the first and second electrodes 14 and 18 allow electron-hole pairs to combine within the corresponding organic layer, so that light or other radiation may be emitted from the electronic device. In a display, rows and columns can be given signals to activate the appropriate pixels (electronic devices) to render a display to a viewer in a human-understandable form.

During operation of a radiation detector, such as a photodetector, sense amplifiers may be coupled to the first and second electrodes of the array to detect significant current flow when radiation is received by the electronic device. In a voltaic cell, such as a photovoltaic cell, light or other radiation can be converted to energy that can flow without an external energy source. After reading this specification, skilled artisans are capable of designing the electronic devices, peripheral circuitry, and potentially remote circuitry to best suit their particular needs or desires.

The following examples demonstrate that an OLED device's performance may be significantly improved by application of an optical resonator according to various embodiments of the present invention. The following specific examples are meant to illustrate and not limit the scope of the invention.

### Example 1

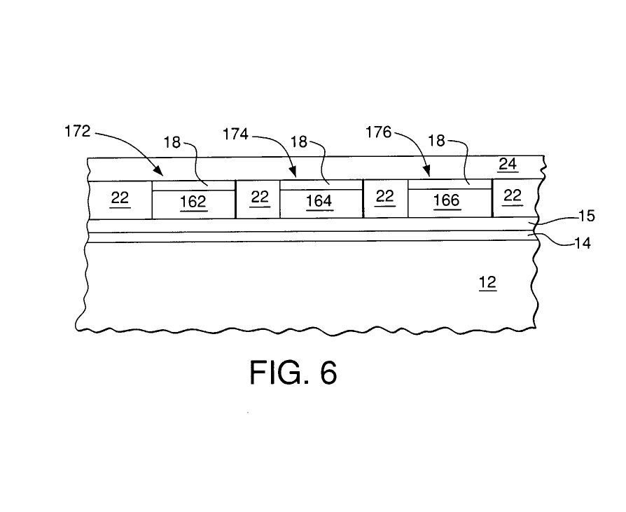

This example demonstrates that an optical resonator fabricated on the cathode side of an OLED device may improve the color coordinates of the primary emitters as well as the contrast ratio of the device. FIG. 6 depicts an optical resonator fabricated on the cathode side of an OLED device. A nominal four-inch, full-color active matrix display panel can be used. Substrate 12 is glass, and first electrode 14 is ITO. First electrode 14 may serve as an anode.

On top of first electrode 14, transparent layer 15 comprising polyaniline (“PANI”) or poly(3,4-ethylenedioxythiophene) (“PEDOT”) layer is spin-coated as a buffer layer with thickness varied in a broad range from approximately 30 nm to 500 nm. Blue, green and red emitter solutions are ink-jetted onto the buffer layer at respective positions. The combinations of the buffer layer and emitters are illustrated as organic layers 162, 164 and 166. Second electrodes (Ba and Al) 18 are evaporated under vacuum and have partial reflectance. The combination of organic layers 162, 164 and 166 with second electrodes 18 form electronic devices 172, 174 and 176, respectively. Electronic devices 172, 174 and 176 may serve as primary color emitters. ITO layer 24 can be sputtered on top of the cathode. To make an optical resonator with the resonant modes discussed above, the light path length may be about 2560 nm. Because the refraction index of ITO is about 1.5, the thickness of the ITO layer may be about 853 nm. A thick silver layer was deposited onto the ITO to finalize the optical resonator.

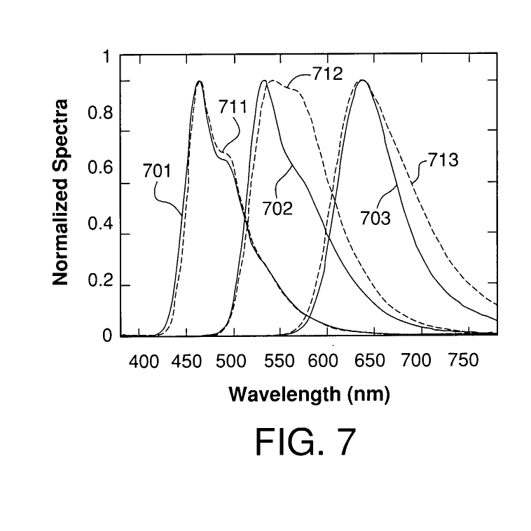

The emission spectra of the primary color emitters with and without the optical resonator are illustrated in FIG. 6. The CIE color coordinates of the red, green and blue emitters are (0.667, 0.331), (0.423, 0.559) and (0.157, 0.249), respectively. The emission spectra of the primary color emitters without the optical resonator on the cathode side are illustrated as lines 711, 712 and 713 (corresponding to blue, green and red, respectively) in FIG. 7. After the optical resonator was coupled into the device, the CIE color coordinates of red, green and blue emitters were improved to (0.675, 0.323), (0.384, 0.590) and (0.157, 0.230), respectively. The emission spectra of the primary color emitters with the optical resonator on the cathode side are illustrated as lines 701, 702 and 703 (corresponding to blue, green and red, respectively) in FIG. 7.

The red and green primaries were improved more than the blue primary due to the working structure of the new device. Assuming the emitted light is isotropic, half of the light is emitted upward toward the anode (e.g., first electrode 14) while half of light is emitted downward toward the cathode (e.g., second electrode 18). The downward emission is modified by the optical resonator, reflected back toward the anode and eventually mixed with the upward emission to give the final emission spectrum. By comparing the blue resonant mode in FIG. 3 (illustrated as line 301) with blue emission without optical resonator in FIG. 7 (line 711), it was discovered that the downward blue emission was reduced by the optical resonator. As a result, the final emission was dominated by the upward emission, which was not altered by the optical resonator.

The contrast ratio of the nominal four-inch panel without a circular polarizer or the optical resonator has a contrast ratio of around 15:1. With the optical resonator, the contrast ratio is approximately 35:1 without a circular polarizer. Thus, the improvement factor is more than two.

### Example 2

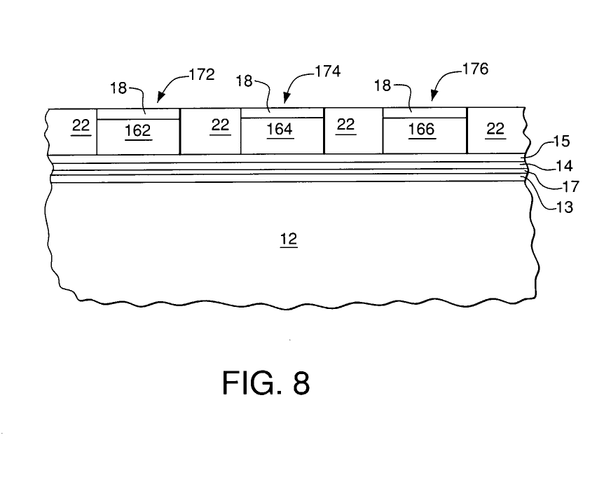

This example shows that an OLED device made inside an optical resonator improves both the color coordinates of the primary emitters and the contrast ratio of the resulting device. References are made to FIG. 8 as appropriate. A nominal four-inch full color active matrix display panel can be used. Substrate 12 is glass. Before forming first electrode 14, a 10 nm Cr layer is deposited as bonding layer 13 and a thin layer of Au (layer 17) is evaporated to serve as a partially-reflective side of the optical resonator. The thickness of the Au may be selected to provide a reflectance sufficient to make the finesse of the optical resonator equal to two. First electrode 14, formed from ITO, is sputtered on top of Au layer 17. On top of first electrode 14, transparent layer 15 comprising polyaniline (“PANI”) or poly(3,4-ethylenedioxythiophene) (“PEDOT”) layer is spin-coated as a buffer layer with thickness varied in a broad range from approximately 30 nm to 500 nm.

Blue, green and red emitter solutions are ink-jetted onto the buffer layer at respective positions. The combinations of the buffer layer and emitters are illustrated as organic layers 162, 164 and 166. Unlike the configuration discussed above in connection with example 1, second electrodes (Ba and Al) 18 are evaporated under high vacuum successively to have substantially complete reflectance. The combination of organic layers 162, 164 and 166 with second electrodes 18 form electronic devices 172, 174 and 176, respectively. Electronic devices 172, 174 and 176 may serve as primary color emitters.

Thus, an optical resonator is formed between Au layer 17 and second electrodes 18. The ITO of first electrode 14 may serve two functions. One may be to serve as a part of the anode, and the other may be to adjust the light path length. As the device is inside the optical resonator, the optical resonator includes many layers: first electrode 14, transparent layer 15, etc. As a result, the light path length is:

$$2 {\sum }_{i} {n}_{i} {d}_{i} \qquad ( 4 )$$

wherein:
nᵢ is the index of refraction of each layer;
dᵢ is the thickness of each layer; and
i is the index of each layer.

To make an optical resonator with the resonant modes discussed above, therefore, the light path length is set to be 2560 nm, i.e.,

$$2 {\sum }_{i} {n}_{i} {d}_{i} = 2560 nm .$$

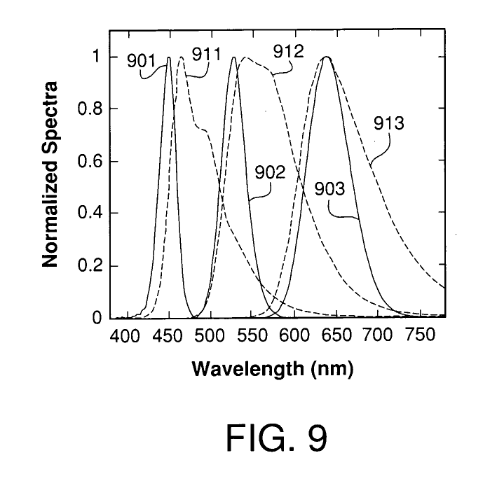

The emission spectra of the primary color emitters without the optical resonator are illustrated as dashed lines 911, 912 and 913 (corresponding to blue, green and red, respectively) in FIG. 9. The CIE color coordinates of the red, green and blue emitters was improved from (0.667, 0.331), (0.423, 0.559) and (0.157, 0.249) to (0.687, 0.312), (0.176, 0.756) and (0.156, 0.019), respectively. The emission spectra of the primary color emitters with the device inside the optical resonator are illustrated as lines 901, 902 and 903 (corresponding to blue, green and red, respectively) in FIG. 9.

The contrast ratio of the nominal four-inch panel improved from approximately 15:1 to approximately 35:1. Thus, the improvement factor is more than two. When a thin layer of anti-reflection film is coated on the surface of substrate 12, a contrast ratio of more than 100:1 is achieved.

### Example 3

In Example 2 discussed above, the device structure was a “bottom emission” device (i.e., light is emitted on the anode side of the device). In AMOLED technology, for example, it may be desirable to have a top emission structure, which may have a larger aperture ratio than a bottom emission structure. Larger aperture ratio tends to lower the light intensity requirements on the OLED emitters, which, in turn, tends to extend the lifetime of the emitters. Example 3 shows that a top emission OLED device made inside the optical resonator may improve the color coordinates of the primary emitters and the contrast ratio of the device. References are again made to FIG. 8 as appropriate.

A nominal four-inch full color active matrix display panel can be used. Substrate 12 is glass. Before forming first electrode 14, a 10 nm Cr layer is deposited as bonding layer 13 and a thick layer of Au (layer 17) is evaporated to serve as a substantially completely reflective side of the optical resonator. First electrode 14, formed from ITO, is sputtered on top of Au layer 17. On top of first electrode 14, transparent layer 15 comprising polyaniline (“PANI”) or poly(3,4-ethylenedioxythiophene) (“PEDOT”) layer is spin-coated as a buffer layer with thickness varied in a broad range from approximately 30 nm to 500 nm. Blue, green and red emitter solutions are ink-jetted onto the buffer layer at respective positions. The combinations of the buffer layer and emitters are illustrated as organic layers 162, 164 and 166. Unlike the configuration discussed above in connection with example 2, second electrodes (Ba and Al) 18 are evaporated under high vacuum successively to have partial reflectance. The thickness of second electrodes 18 may be selected to provide a reflectance sufficient to make the finesse of the optical resonator equal to two. The combination of organic layers 162, 164 and 166 with second electrodes 18 form electronic devices 172, 174 and 176, respectively. Electronic devices 172, 174 and 176 may serve as primary color emitters.

Thus, an optical resonator is formed between Au layer 17 and second electrodes 18. As was the case in example 2, the ITO of first electrode 14 may serve two functions. One may be to serve as a part of the anode, and the other may be to adjust the light path length. As the device is inside the optical resonator, the optical resonator includes many layers: first electrode 14, transparent layer 15, etc. As a result, the light path length is:

$$2 {\sum }_{i} {n}_{i} {d}_{i} \qquad ( 4 )$$

wherein:
nᵢ is the index of refraction of each layer;
dᵢ is the thickness of each layer; and
i is the index of each layer.

To make an optical resonator with the resonant modes discussed above, therefore, the light path length is set to be 2560 nm, i.e.,

$$2 {\sum }_{i} {n}_{i} {d}_{i} = 2560 nm .$$

As was the case in Example 2, the emission spectra of the primary color emitters without the optical resonator are illustrated as dashed lines 911, 912 and 913 (corresponding to blue, green and red, respectively) in FIG. 9. The CIE color coordinates of the red, green and blue emitters was again improved from (0.667, 0.331), (0.423, 0.559) and (0.157, 0.249) to (0.687, 0.312), (0.176, 0.756) and (0.156, 0.019), respectively. The emission spectra of the primary color emitters with the device inside the optical resonator are illustrated as lines 901, 902 and 903 (corresponding to blue, green and red, respectively) in FIG. 9.

The contrast ratio of the nominal four-inch panel improved from approximately 15:1 to approximately 35:1. Thus, the improvement factor is more than two. When a thin layer of anti-reflection film is coated on the surface of substrate 12, a contrast ratio of more than 100:1 is achieved.

### Example 4

In an embodiment involving a full color display, each pixel may include 3 sub-pixels for each primary color: blue, green and red. Due to practical reasons, the layout of the full color pixel is lateral in which 3 sub-pixels are laid side by side. (See, for example, FIGS. 4-6 and 8 for example configurations of such a layout). By making a full color pixel in a stacked configuration, not only could the resolution of the display be increased by a factor of 3, but also the light intensity requirement for each sub-pixel could be lowered by a factor of 3. As a result, the lifetime of a resulting OLED emitter may be significantly extended. For a high content information display, for example, a stacked full color OLED emitter may be more appropriate than a lateral configuration. The present example demonstrates that a stacked full color OLED emitter inside an optical resonator improves the color coordinates of the primary emitters and the contrast of a resulting display.

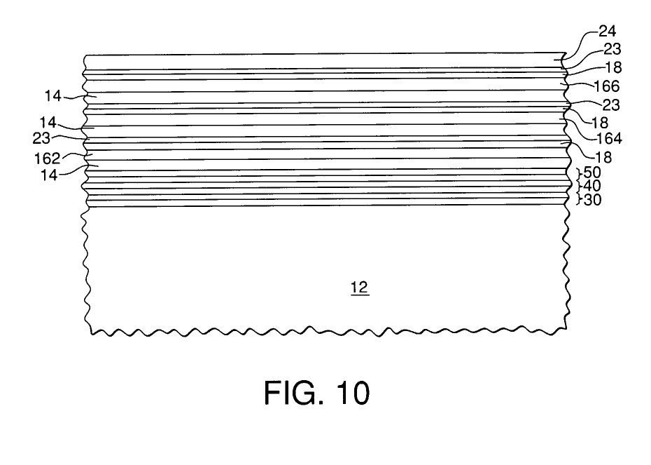

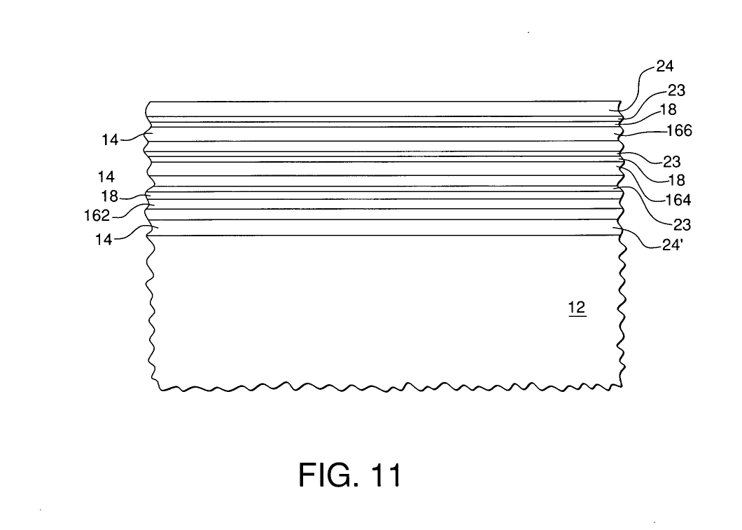

Two device structures are illustrated in FIGS. 10 and 11. Reference numbers in FIGS. 10 and 11 are consistent with those used above in connection with FIGS. 4-6 and 8 and reflect the stacked configuration discussed above. In addition, passivation layer 23 is sputtered between each primary emitter. Again, the light path length is:

$$2 {\sum }_{i} {n}_{i} {d}_{i} \qquad ( 4 )$$

wherein:
nᵢ is the index of refraction of each layer;
dᵢ is the thickness of each layer; and
i is the index of each layer.

Passivation layers 23 act as insulation layer between two adjacent electrodes and adjust the light path length to satisfy the resonant condition:

$$2 {\sum }_{i} {n}_{i} {d}_{i} = 2560 nm .$$

The light path length can also be adjusted by first electrode 14. The device depicted in FIG. 10 is a top emission device (i.e., light is emitted on the cathode side of the device). A broad bands Bragg reflector may be used to be the optical resonator's surface having substantially complete reflectance. The Bragg reflector is shown in FIG. 10 has three mirror stacks 30, 40 and 50, wherein each mirror stack 30, 40 and 50 comprises a pair of layers. Mirror 24 of metal or conductive oxide is evaporated or sputtered under high vacuum to have partial reflectance. The reflectance is controlled to give a finesse that is substantially equal to 2.

The device illustrated in FIG. 11 is a traditional bottom emission device (i.e., light is emitted on the anode side of the device). Mirror 24 is made of metal or conductive oxide that is evaporated or sputtered under high vacuum to have substantially complete reflectance. Mirror 24′ is made of metal or conductive oxide that is evaporated or sputtered under high vacuum to have partial reflectance to give the required finesse. It was determined that mirror 24 having substantially complete reflectance can be either be a metal mirror or a broad bands Bragg reflector and that mirror 24 with substantially complete reflectance can be implemented either on the anode or cathode sides of a device (making either a top or bottom emission device, respectively). The arrangement of the three primary emitters inside the optical resonator can be arbitrary, provided that one emitter's primary emission is not absorbed by the other two emitters. Because the resonant modes of the optical resonator is as same as the one shown in FIG. 3, the devices of FIGS. 10 and 11 achieved performance improvements illustrated in FIG. 7 and discussed above in connection with Example 2.

Note that not all of the activities described above in the general description or the examples are required, that a portion of a specific activity may not be required, and that one or more further activities may be performed in addition to those described. Still further, the order in which activities are listed are not necessarily the order in which they are performed. After reading this specification, skilled artisans will be capable of determining what activities can be used for their specific needs or desires.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Many aspects and embodiments have been described above and are merely exemplary and not limiting. After reading this specification, skilled artisans appreciate that other aspects and embodiments are possible without departing from the scope of the invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

1. An electronic device, comprising:
a first electronic component designed to be photoactive to a first radiation having a first wavelength;
a second electronic component designed to be photoactive to a second radiation having a second wavelength; and
a cavity that defines an optical resonator, where the cavity has a length such that the optical resonator resonates in successive resonant modes that locate at the first and second wavelengths.

2. The electronic device of claim 1, wherein the cavity is formed from a first and a second layer of the electronic device.

3. The electronic device of claim 1, wherein the cavity further comprises at least one resonating layer through which said first and second radiation resonates.

4. The electronic device of claim 3, wherein said resonating layer is bordered on one side by a first reflective layer and on a second side by a second reflective layer, wherein said first reflective layer reflects into said resonating layer at least a portion of said first and second radiation.

5. The electronic device of claim 4, wherein said second reflective layer at least partially permits said first and second radiation to pass through said second reflective layer.

6. The electronic device of claim 3, wherein said electrical device further comprises a plurality of layers, and wherein said resonating layer is bordered on one side by an interface formed by at least two of said plurality of layers.

7. The electronic device of claim 1, further comprising:
a third electronic component designed to be photoactive to a third radiation having a third wavelength; and wherein the cavity length of said optical resonator is such that the optical resonator further resonates in a resonant mode that locates at the third wavelength.

8. The electronic device of claim 1, wherein the electronic device is formed within the optical resonator.

9. The electronic device of claim 1, wherein the first and second electronic components are arranged in a stacked or lateral configuration.

10. An organic light emitting device, comprising:
a substrate;
a cathode layer;
an anode layer;
a light-emitting layer that emits light in each of red, green, and blue visible regions through the substrate in response to a current applied between the cathode layer and the anode layer; and
an optical resonator, said optical resonator comprising at least one resonating layer through which said light resonates, where said light resonates in at least three successive resonant modes, and further where said three successive resonant modes correspond to red, green, and blue visible regions.

11. The organic light emitting device of claim 10, wherein said resonating layer is bordered on one side by a first reflective layer and on a second side by a second reflective layer, wherein each of said first and said second reflective layers reflects back into said resonating layer at least some portion of said light resonating through said resonating layer onto said reflective layer.

12. A process for forming an electronic device, comprising:
forming a first electronic component designed to be photoactive to a first radiation having a first wavelength;
forming a second electronic component designed to be photoactive to a second radiation having a second wavelength; and
forming an optical resonator having a cavity length such that the optical resonator resonates in successive resonant modes that locate at the first and second wavelengths.

13. The process of claim 12, further comprising:
forming a substrate;
forming an anode layer; and
forming a cathode layer; wherein the optical resonator is formed on a side of the electronic device corresponding to the cathode layer.

14. The process of claim 12, wherein the optical resonator further comprises at least one resonating layer through which said first and second radiation resonates.

15. The process of claim 14, wherein said resonating layer is bordered on one side by a first reflective layer and on a second side by a second reflective layer, wherein said first reflective layer reflects into said resonating layer at least a portion of said first and second radiation.

16. The process of claim 15, wherein said second reflective layer at least partially permits said first and second radiation to pass through said second reflective layer.

17. The process of claim 12, further comprising:
forming a third electronic component designed to be photoactive to a third radiation having a third wavelength; and wherein the cavity length of said optical resonator is such that the optical resonator further resonates in a resonant mode that locates at the third wavelength.

18. A composition including the electronic device of claim 1.

19. An organic electronic device having an active layer including the electronic device of claim 1.

20. An article useful in the manufacture of an organic electronic device, comprising the electronic device of claim 1.
